(19) United States
(12) Patent Application Publication
(10) Pub. No.: US 2026/0277351 A1
(43) Pub. Date: Sep. 17, 2026

(54) DISPLAY DEVICE AND METHOD FOR MANUFACTURING DISPLAY DEVICE

(71) Applicant: Sharp Display Technology Corporation, Kameyama City, Mie (JP)

(72) Inventor: Jean MUGIRANEZA, Kameyama City, Mie (JP)

(21) Appl. No.: 19/105,181

(22) PCT Filed: Sep. 14, 2022
(86) PCT No.: PCT/JP2022/034313

§ 371 Date: Feb. 20, 2025

(51) Int. Cl. G06F 3/041; G02F 1/1333; G06F 3/044; H10K 59/40

(52) U.S. Cl. CPC G06F 3/0412; G06F 3/0416; G06F 3/0445; G06F 3/0446; G02F 1/13338; G06F 2203/04103; G06F 2203/04105; G06F 2203/04107; H10K 59/40

(57) ABSTRACT

A display device includes: a display surface; a display unit; and a sensor unit provided between the display surface and the display unit, wherein the sensor unit includes a first conductive layer including a driving electrode and a pressure detecting electrode that are flush with each other in such a shape as to engage at least partly, a second conductive layer including a touch detecting electrode provided closer to the display surface than the first conductive layer so as to overlap at least a part of the pressure detecting electrode in a plan view, and an elastic layer provided at least between the first conductive layer and the display unit, having a Young's modulus of 0.1 MPa or less, and having a thickness equal to or smaller than an engagement pitch value between the driving electrode and the pressure detecting electrode in the first conductive layer.

### TECHNICAL FIELD

The present disclosure relates to a display device and a method for manufacturing the display device.

### BACKGROUND ART

In recent years, display devices each including a sensor unit that detects a touch and a pressure onto its display surface, and methods for manufacturing such display devices have been researched and developed.

Patent Literature 1 describes a sensor unit that detects a touch and a pressure onto its display surface, wherein the sensor unit includes the following: a first touch electrode acting as one of a driving electrode and a detection electrode; a pressure reacting member containing a piezoelectric material having piezoelectric effect, and provided so as to cover the first touch electrode; and a second touch electrode acting as the other of the driving electrode and detection electrode provided on the pressure reacting member.

Patent Literature 2 describes a sensor unit that detects a touch and a pressure onto its display surface, wherein the sensor unit includes the following: a first electrode and a second electrode that are flush with each other, the first electrode acting as a driving electrode, the second electrode acting as a detection electrode; and a piezoelectric layer containing an organic piezoelectric material and provided so as to cover the first and second electrodes.

### CITATION LIST

### Patent Literatures

Patent Literature 1: U.S. Pat. No. 10,720,474
Patent Literature 2: United States Unexamined Patent Application Publication No. 2020/0117297

### SUMMARY

### Technical Field

The sensor unit in Patent Literature 1, which detects a touch and a pressure onto the display surface, needs to include a pressure reacting member containing a piezoelectric material having piezoelectric effect, in order to detect a pressure onto the display surface. The sensor unit in Patent Literature 2, which detects a touch and a pressure onto the display surface, needs to include a piezoelectric layer containing an organic piezoelectric material having piezoelectric effect, in order to detect a pressure onto the display surface.

Further, the sensor units in Patent Literatures 1 and 2, which detect a touch and a pressure onto their display surfaces, detect a touch and a pressure onto the display surface by the use of a common detection electrode. This unfortunately requires separate driving: a first period for detecting the touch onto the display surface; and a second period for detecting the pressure onto the display surface.

In view of the above problem, one aspect of the present disclosure is to provide a display device and a method for manufacturing the display device that need no layer having piezoelectric effect, that can set a period for detecting a pressure onto its display surface irrespective of a period for detecting a touch onto the display surface, and that can prevent noise influence from its display unit during the detection of the touch onto the display surface.

### Solution to Problem

To solve the above problem, a display device in the present disclosure is provided with the following:
a display surface;
a display unit including a display element configured to emit light toward the display surface; and
a sensor unit provided between the display surface and the display unit, and configured to detect a touch and a pressure onto the display surface,
wherein the sensor unit includes the following:
a first conductive layer including a driving electrode and a pressure detecting electrode that are flush with each other in such a shape as to engage at least partly,
a second conductive layer including a touch detecting electrode provided closer to the display surface than the first conductive layer so as to overlap at least a part of the pressure detecting electrode in a plan view, and
an elastic layer provided at least between the first conductive layer and the display unit, having a Young's modulus of 0.1 MPa or less, and having a thickness equal to or smaller than an engagement pitch value between the driving electrode and the pressure detecting electrode in the first conductive layer.

To solve the above problem, in a method for manufacturing a display device in the present disclosure, the display device is provided with the following:
a display surface;
a display unit including a display element configured to emit light toward the display surface; and
a sensor unit provided between the display surface and the display unit, and configured to detect a touch and a pressure onto the display surface.

The method is provided with a step of forming the sensor unit, the step including the following:
a step of forming a first conductive layer including a driving electrode and a pressure detecting electrode that are flush with each other in such a shape as to engage at least partly;
a step of forming, closer to the display surface than the first conductive layer, a second conductive layer including a touch detecting electrode overlapping at least a part of the pressure detecting electrode in a plan view; and
a step of forming an elastic layer provided at least between the first conductive layer and the display unit, having a Young's modulus of 0.1 MPa or less, and having a thickness equal to or smaller than an engagement pitch value between the driving electrode and the pressure detecting electrode in the first conductive layer.

### Advantageous Effect of Disclosure

One aspect of the present disclosure can provide a display device and a method for manufacturing a display device that need no layer having piezoelectric effect, that can set a period for detecting a pressure onto its display surface irrespective of a period for detecting a touch onto the display surface, and that can prevent noise influence from its display unit during the detection of the touch onto the display surface.

### BRIEF DESCRIPTION OF DRAWINGS

FIG. 1 is a cross-sectional view of the schematic configuration of a display device according to a first embodiment.

FIG. 2 is a perspective view of the schematic electrode configuration of a sensor unit included in the display device according to the first embodiment.

FIG. 3 is a plan view of the schematic electrode configuration of the sensor unit included in the display device according to the first embodiment.

FIG. 4 is a diagram illustrating the relationship between the detection accuracy of the sensor unit included in the display device according to the first embodiment, and the thickness of an elastic layer included in the same.

FIG. 5 is a plan view of the schematic electrode configuration of another sensor unit that can be included in the display device according to the first embodiment.

FIG. 6 is a cross-sectional view of the schematic configuration of a display device according to a second embodiment.

FIG. 7 is a cross-sectional view of the schematic configuration of a display device according to a third embodiment.

FIG. 8 is a diagram illustrating an example of how to drive the sensor unit included in the display device according to the third embodiment.

FIG. 9 is a diagram illustrating another example of how to drive the sensor unit included in the display device according to the third embodiment.

FIG. 10 is a perspective view of the schematic electrode configuration of the sensor unit included in the display device according to the third embodiment.

FIG. 11 is a plan view of the schematic electrode configuration of the sensor unit included in the display device according to the third embodiment.

FIG. 12 is a cross-sectional view of a portion where a driving electrode and a pressure detecting electrode intersect with each other, in the sensor unit included in the display device according to the third embodiment.

FIG. 13 is a plan view of the schematic electrode configuration of another sensor unit that can be included in the display device according to the third embodiment.

FIG. 14 is a plan view of the schematic electrode configuration of further another sensor unit that can be included in the display device according to the third embodiment.

### DESCRIPTION OF EMBODIMENTS

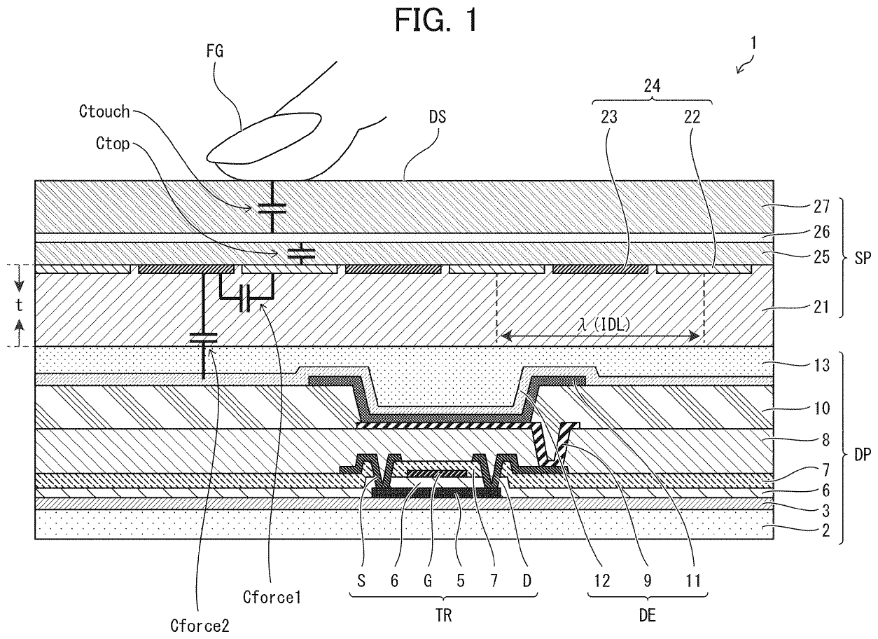

The following describes embodiments of the present disclosure with reference to FIGS. 1 through 14. Hereinafter, for convenience in description, a constituent having the same function as that of a constituent described in a particular embodiment will be denoted by the same sign, and its description will be omitted in some cases.

### First Embodiment

FIG. 1 is a cross-sectional view of the schematic configuration of a display device 1 according to the first embodiment.

As illustrated in FIG. 1, the display device 1 includes the following: a display surface DS; a display unit DP including a display element DE configured to emit light toward the display surface DS; and a sensor unit SP provided between the display surface DS and the display unit DP, and configured to detect a touch and a pressure onto the display surface DS. It is noted that the touch and a pressure onto the display surface DS may be performed by a human finger FG, or an input pen not shown; any conductor may be used.

The display unit DP provided in the display device 1 includes the following on a substrate 2 in the stated order from the substrate 2: a barrier layer 3; a thin-film transistor layer including a transistor TR; a flattening film 8; the display element DE and an edge cover 10; and a sealing layer 13.

When the display device 1 is a flexible display device, a flexible resin substrate, including polyimide, polyester resin, acrylic resin, polycarbonate, and carbon fiber reinforced plastic, may be used as the substrate 2, and a metal substrate containing at least one of stainless steel, aluminum, titanium, and copper may be used as long as the flexibility of the substrate 2 can be achieved.

When the display device 1 is an inflexible display device, a glass substrate for instance can be used as the substrate 2.

The barrier layer 3 is a layer that prevents foreign substances, such as water and oxygen, from entering the transistor TR and display element DE, and the barrier layer 3 can be formed from, for instance, a silicon oxide film, a silicon nitride film, or a silicon oxide nitride film, all of which are formed through chemical vapor deposition (CVD), or can be formed from, for instance, a laminate of these films.

A transistor-TR portion, which is a portion of the thin-film transistor layer including the transistor TR, includes the following: a semiconductor film 5; a first insulating film 6; a gate electrode G; a second insulating film 7; a source electrode S and a drain electrode D. A portion excluding the transistor-TR portion of the thin-film transistor layer including the transistor TR includes the first insulating film 6 and the second insulating film 7.

The semiconductor film 5 may be made of, for instance, low-temperature polysilicon (LTPS) or an oxide semiconductor (e.g., an In—Ga—Zn—O semiconductor). Although this embodiment describes, by way of example, an instance where the transistor TR has a top-gate structure, the transistor TR may have a bottom-gate structure.

The first insulating film 6 and the second insulating film 7 can be formed from, for instance, a silicon oxide film, a silicon nitride film, or a silicon oxide nitride film, all of which are formed through CVD, or can be formed from, for instance, a laminate of these films.

The gate electrode G, the source electrode S, and the drain electrode D can be formed from, for instance, a metal monolayer film or metal laminated film containing at least one of aluminum, tungsten, molybdenum, tantalum, chromium, titanium, and copper.

The flattening film 8 can be made of, for instance, an organic material that can be applied, such as polyimide or acrylic.

This embodiment describes, by way of example, an instance where the display element DE included in an individual-colored subpixel of the display device 1 is a light-emitting element including an emission layer, examples of which include an organic light-emitting diode (OLED) provided with an organic emission layer, and a quantum-dot light-emitting diode (QLED) including a quantum-dots-containing emission layer; however, the display element DE may be a liquid-crystal display element including a liquid-crystal layer.

When the display element DE is an OLED or a QLED, the display element DE includes an anode that is a first electrode 9 above the flattening film 8, a functional layer 11 including an emission layer, and a cathode that is a second electrode 12.

Although this embodiment describes, by way of example, an instance where the display element DE, which is either an OLED or a QLED, has a known staked structure, the display element DE, which is either an OLED or a QLED, may have a reverse stacked structure. The known stacked structure means that the anode that is the first electrode 9, the functional layer 11 including the emission layer, and the cathode that is the second electrode 12 are stacked in the stated order from the substrate 2. It is noted that in the known stacked structure, the functional layer 11 including the emission layer can be formed by, but not limited to, stacking a hole injection layer, a hole transport layer, the emission layer, an electron transport layer, and an electron injection layer sequentially from the first electrode 9. On the other hand, the reverse stacked structure means that the cathode that is the first electrode 9, the functional layer 11 including the emission layer, and the anode that is the second electrode 12 are stacked in the stated order from the substrate 2. It is noted that in the reverse stacked structure, the functional layer 11 including the emission layer can be formed by, but not limited to, stacking an electron injection layer, an electron transport layer, the emission layer, a hole transport layer, and a hole injection layer sequentially from the first electrode 9.

As described above, the display element DE in this embodiment is a top-emission OLED or QLED that emits light toward the display surface DS. In the known stacked structure, where the second electrode 12 or cathode is disposed above the first electrode 9 or anode, achieving a top-emission type requires the first electrode 9 or anode to be made of an electrode material that reflects visible light, and requires the second electrode 12 or cathode to be made of an electrode material that transmits visible light. On the other hand, in the reverse stacked structure, where the second electrode 12 or anode is disposed above the first electrode 9 or cathode, achieving a top-emission type requires the first electrode 9 or cathode to be made of an electrode material that reflects visible light, and requires the second electrode 12 or anode to be made of an electrode material that transmits visible light.

The electrode material that reflects visible light may be any material that can reflect visible light and is conductive; usable examples include, but not limited to, a metal material, such as Al, Mg, Li or Ag, an alloy of the metal material, a stack of the metal material and a transparent metal oxide (e.g., an indium tin oxide, an indium zinc oxide, and an indium gallium zinc oxide), and a stack of the alloy and transparent metal oxide.

On the other hand, the electrode material that transmits visible light may be any material that can transmit visible light and is conductive; examples include a transparent metal oxide (e.g., an indium tin oxide, an indium zinc oxide, and an indium gallium zinc oxide), a thin film made of metal, such as Al or Ag, and a nanowire made of metal, such as Al or Ag.

The edge cover 10, which covers the edge of the first electrode 9, can be formed by, for instance, applying an organic material, such as polyimide or acrylic, followed by patterning it through photolithography.

The sealing layer 13 prevents foreign substances, such as water and oxygen, from permeating the display element DE. Although the sealing layer 13 in this embodiment is formed from two inorganic films and one organic film provided between the two inorganic films, the order of stacking two inorganic films and one organic film is not limited to this instance. Furthermore, the sealing layer 13 may be formed from only an inorganic film or only an organic film; alternatively, the layer may be formed from one inorganic film and two organic films; alternatively, the layer may be formed from two or more inorganic films and two or more organic films. The inorganic films included in the sealing layer 13 can be formed from, for instance, a silicon oxide film, a silicon nitride film, or a silicon oxide nitride film, all of which are formed through CVD, or a laminate of these films. The organic film included in the sealing layer 13 is an organic light-transparent film with flattening effect and can be made of, for instance, an organic material that can be applied, such as acrylic. The organic film may be formed through ink-jet printing for instance.

The display element DE in this embodiment is an OLED or a QLED; thus, the display unit DP includes the sealing layer 13 provided so as to cover the display element DE, and the sensor unit SP is provided between the display surface DS and the sealing layer 13.

On the other hand, when the display element DE is a liquid-crystal display element, the display unit DP may not include the sealing layer 13 provided so as to cover the display element DE.

It is noted that when the display device DE is a liquid-crystal display element, and the display device 1 is a flexible display device, the foregoing liquid-crystal display element is preferably a reflective liquid-crystal display element, and that when the display device 1 is an inflexible display device, the foregoing liquid-crystal display element may include a backlight separately.

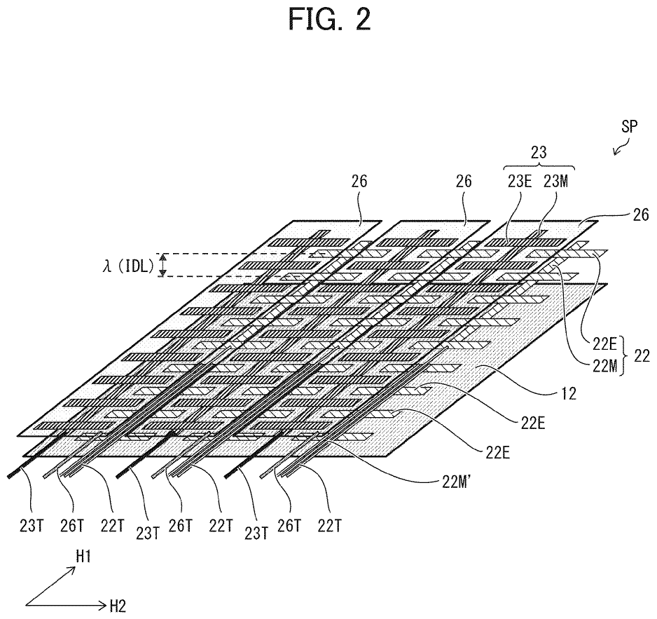

FIG. 2 is a perspective view of the schematic electrode configuration of the sensor unit SP included in the display device 1 according to the first embodiment.

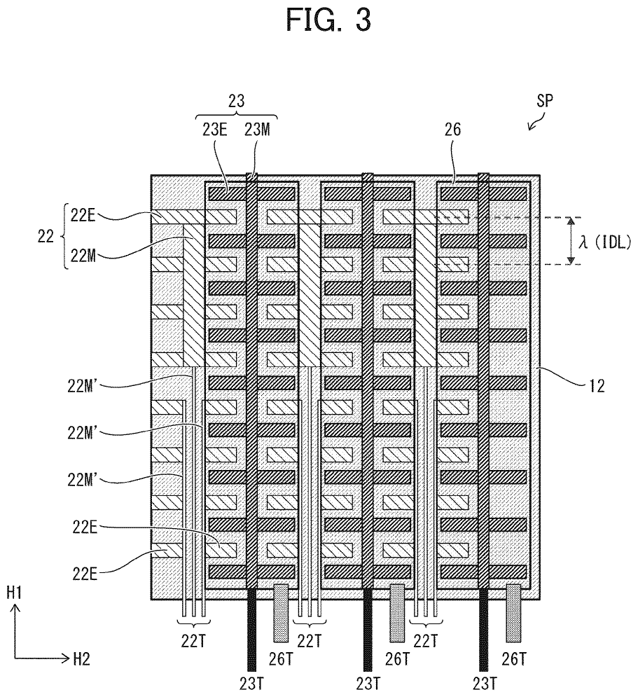

FIG. 3 is a plan view of the schematic electrode configuration of the sensor unit SP included in the display device 1 according to the first embodiment.

It is noted that FIGS. 2 and 3 illustrate the electrode configuration in part of the sensor unit SP; such an electrode configuration is repeated in the entire sensor unit SP.

It is also noted that although FIGS. 2 and 3 omit, in a part of the sensor unit SP, illustration of a touch detecting electrode 26 overlapping a plurality of branch electrode portions 22E of the driving electrode 22 in plan view, this plurality of branch electrode portions 22E of the driving electrode 22 overlaps the touch detecting electrode 26 in plan view.

As illustrated in FIGS. 1, 2, and 3, the sensor unit SP included in the display device 1 includes the following: a first conductive layer 24 including the driving electrode 22 and a touch detecting electrode 23 that are flush with each other, on the lower surface of an insulating layer 25 in this embodiment, in such a shape as to engage at least partly; a second conductive layer including the touch detecting electrode 26 provided closer to the display surface DS than the first conductive layer 24 so as to overlap at least a part of a pressure detecting electrode 23 in plan view; and an elastic layer 21 provided at least between the first conductive layer 24 and the display unit DP, having a Young's modulus of 0.1 MPa or less, and having a thickness t equal to or smaller than an engaging pitch value 2 (IDL) between the driving electrode 22 and pressure detecting electrode 23 in the first conductive layer 24.

As illustrated in FIGS. 2 and 3, the engagement pitch λ (IDL) between the driving electrode 22 and pressure detecting electrode 23 in the first conductive layer 24 means the pitch between two of the branch electrode portions 22E adjacent to each other in a first direction H1 of the driving electrode 22, in a portion formed in such a shape that the driving electrode 22 and the pressure detecting electrode 23 engage. That is, since the plurality of branch electrode portions 22E each has an identical width in the first direction, the engagement pitch λ (IDL) between the driving electrode 22 and pressure detecting electrode 23 in the first conductive layer 24 is a value obtained by summing the width of the branch electrode portion 22E in the first direction and the interval between two of the branch electrode portions 22E adjacent to each other in the first direction HI.

As illustrated in FIGS. 2 and 3, a plurality of driving electrodes 22 each includes the following: trunk electrode portions 22M and 22M′ extending in the first direction H1; and the plurality of branch electrode portions 22E extending in a second direction H2 that is orthogonal to the first direction H1, and electrically connected to the trunk electrode portions 22M and 22M′. A plurality of pressure detecting electrodes 23 each includes the following: a trunk electrode portion 23M extending in the first direction H1; and a plurality of branch electrode portions 23E extending in the second direction H2 that is orthogonal to the first direction HI, and electrically connected to the trunk electrode portion 23M.

As illustrated in FIGS. 2 and 3, the plurality of driving electrodes 22 in this embodiment includes driving electrodes with three different kinds of shapes. The first driving electrode 22 includes the following: a trunk electrode portion 22M′ extending in the first direction HI; and a plurality of branch electrode portions 22E extending in the second direction H2, provided only on the left side of the trunk electrode portion 22M′, and electrically connected to the trunk electrode portion 22M′. The second driving electrode 22 includes the following: a trunk electrode portion 22M′ extending in the first direction HI; a trunk electrode portion 22M wider than the trunk electrode portion 22M′ in the second direction H2, and extending in the first direction HI; and a plurality of branch electrode portions 22E extending in the second direction H2, provided on both of the right and left sides of the trunk electrode portion 22M, and electrically connected to the trunk electrode portion 22M. The third driving electrode 22 includes the following: a trunk electrode portion 22M′ extending in the first direction HI; and a plurality of branch electrode portions 22E extending in the second direction H2, provided only on the right side of the trunk electrode portion 22M′, and electrically connected to the trunk electrode portion 22M′. It is noted that each of the first, second and third driving electrodes 22 is supplied with a driving signal from one end 22T.

The plurality of driving electrodes 22 may be sequentially driven one by one from, for instance, the left to right sides from the driving electrode 22 whose end 22T is located on the leftmost side in FIG. 3, to the driving electrode 22 whose end 22T is located on the rightmost side in FIG. 3. Driving the driving electrodes 22 in this manner generates a capacitance Ctop illustrated in FIG. 1, between the driving electrode 22 being driven and the touch detecting electrode 26. The capacitance Ctop is maintained as it is when the display surface DS is not touched by a conductor, such as the finger FG, but when the display surface DS is touched by a conductor, such as the finger FG, a capacitance Ctouch illustrated in FIG. 1 is generated, and thus, the capacitance Ctop is changed by the influence of the capacitance Ctouch, so that the position of the touch can be detected. The presence or absence of a change in the capacitance Ctop can be checked through the plurality of touch detecting electrodes 26.

As illustrated in FIGS. 2 and 3, the plurality of touch detecting electrodes 26 can check the presence or absence of a change in the capacitance Ctop by, for example, extracting, during a driving period of the foregoing first driving electrode 22, a detected signal from an end 26T of one of the touch detecting electrode 26 that overlaps the first driving electrode 22 in plan view. During the driving period of the foregoing second driving electrode 22, the plurality of touch detecting electrodes 26 can check the presence or absence of a change in the capacitance Ctop by extracting detected signals sequentially from the ends 26T of two of the touch detecting electrodes 26 that overlap the second driving electrode 22 in plan view. During the driving period of the foregoing third driving electrode 22, the plurality of touch detecting electrodes 26 can check the presence or absence of a change in the capacitance Ctop by extracting a detected signal from the end 26T of one of the touch detecting electrodes 26 that overlaps the third driving electrode 22 in plan view.

As illustrated in FIG. 1, the sensor unit SP of the display device 1 can detect the degree of a pressure onto the display surface DS exerted by a conductor, such as the finger FG. In the sensor unit SP of the display device 1, the elastic layer 21 that is elastically deformed in response to a pressure onto the display surface DS exerted by a conductor, such as the finger FG, is provided at least between the first conductive layer 24 and the display unit DP.

As illustrated in FIG. 1, driving the driving electrode 22 generates a capacitance Cforce1 between the driving electrodes 22 and pressure detecting electrode 23 adjacent to each other in the first conductive layer 24, and generates a capacitance Cforce2 between the driving electrode 22 and the second electrode 12, which is maintained at a constant potential during driving of the display unit DP.

Each of the capacitances Cforce1 and Cforce2 is maintained as it is when there is no pressure onto the display surface DS exerted by a conductor, such as the finger FG, but when there is a pressure onto the display surface DS exerted by a conductor, such as the finger FG, each of the capacitances Cforce1 and Cforce2 is changed by a deformation of the elastic layer 21 corresponding to the pressure's intensity.

As illustrated in FIGS. 2 and 3, the plurality of pressure detecting electrode 23 can check the presence or absence of changes in the capacitances Cforce1 and Cforce2 by, for example, extracting, during the driving period of the foregoing first driving electrode 22, a detected signal from an end 23T of one of the pressure detecting electrodes 23 that has a portion engaging in the first driving electrode 22. During the driving period of the foregoing second driving electrode 22, the plurality of pressure detecting electrodes 23 can check the presence or absence of changes in the capacitances Cforce1 and Cforce2 by extracting detected signals sequentially from the ends 23T of two of the pressure detecting electrodes 23 that have their portions engaging in the second driving electrode 22. During the driving period of the foregoing third driving electrode 22, the plurality of pressure detecting electrodes 23 can check the presence or absence of changes in the capacitances Cforce1 and Cforce2 by extracting a detected signal from the end 23T of one of the pressure detecting electrodes 23 that has a portion engaging in the third driving electrode 22.

As described above, the sensor unit SP included in the display device 1 according to this embodiment can detect a touch position onto the display surface DS made by a conductor, such as the finger FG, and a pressure onto the display surface DS exerted by the conductor, such as the finger FG, at the same timing. Other than the foregoing, the sensor unit SP included in the display device 1 may detect a touch position onto the display surface DS made by a conductor, such as the finger FG, during a first period, and detect a pressure onto the display surface DS exerted by the conductor, such as the finger FG, during a second period different from the first period. As such, the sensor unit SP included in the display device 1 according to this embodiment can set a period for detecting a pressure onto the display surface DS irrespective of a period for detecting a touch onto the display surface DS.

In addition, the sensor unit SP included in the display device 1 according to this embodiment can detect the intensity of a pressure onto the display surface DS exerted by a conductor, such as the finger FG, by checking changes in the capacitances Cforce1 and Cforce2 caused by a deformation of the elastic layer 21 corresponding to the pressure intensity of the conductor, such as the finger FG, exerted onto the display surface DS. This eliminates the need for the elastic layer 21 to have piezoelectric effect.

In addition, the sensor unit SP included in the display device 1 according to this embodiment, which has the touch detecting electrode 26 provided so as to overlap at least a part of the pressure detecting electrodes 23 in plan view, can prevent noise influence from the display unit DP during detection of a touch position by the use of the touch detecting electrode 26.

The Young's modulus of the elastic layer 21 is set at 0.1 MPa or less for the following reason. Reference is made to the sensitivity of detection of a pressure onto the display surface DS exerted by a conductor, such as the finger FG. Let the conductor, such as the finger FG, exert a pressure of 0.5 to IN inclusive per 1 cm² onto the display surface DS; in this case, setting the Young's modulus of the elastic layer 21 at 0.1 MPa or less can obtain sufficient pressure-detection sensitivity.

This embodiment describes, by way of example, a non-limiting instance where the engagement pitch 2 (IDL) between the driving electrode 22 and pressure detecting electrode 23 in the first conductive layer 24 illustrated in FIGS. 1, 2, and 3 measures 500 μm.

The thickness t of the elastic layer 21 measures 500 μm or less, which is the engagement pitch value λ (IDL), in this embodiment.

It is noted that when the display device 1 is a flexible display device, the thickness t of the elastic layer 21 may measure 200 μm or less in order to achieve endurance against the number of bendings of the elastic layer 21; the thickness t preferably measures 100 μm or less, more desirably measures 50 μm or less, and most desirably measures 25 μm or less.

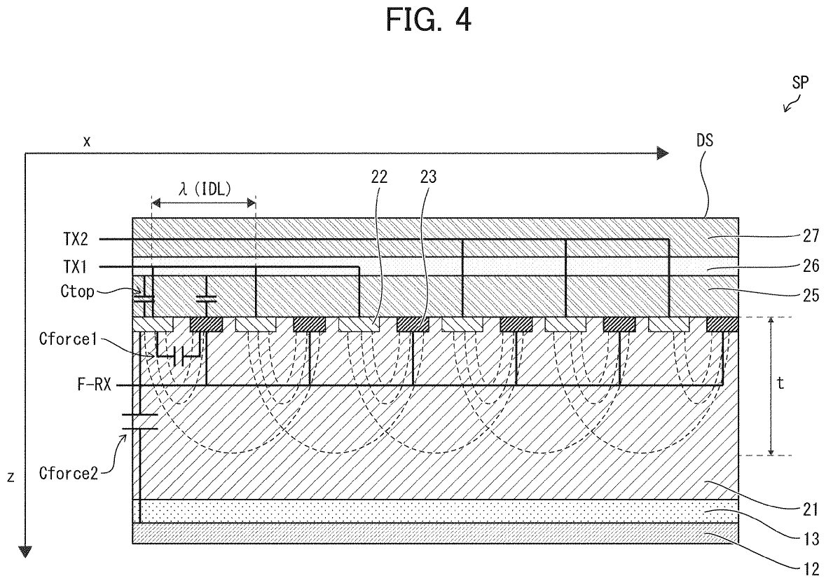

FIG. 4 is a diagram illustrating the relationship between the detection accuracy of the sensor unit SP, which is included in the display device 1 according to the first embodiment, and the thickness of the elastic layer 21, which is included in the same.

FIG. 4 illustrates one example of the electric field between the driving electrode 22 and pressure detecting electrode 23 when the engagement pitch 2 (IDL) between the driving electrode 22 and pressure detecting electrode 23 in the first conductive layer 24 measures 500 μm; in this case, the thickness t of the elastic layer 21 also measures 500 μm, which is a non-limiting measurement.

Let the thickness t of the elastic layer 21 illustrated in FIG. 4 be equal to an impregnation depth, which indicates a depth at which the elastic layer 21 is impregnated with the electric field between the driving electrode 22 and pressure detecting electrode 23; accordingly, the amount of capacitance fluctuation, ΔCtot, in the sensor unit SP is expressed by Expression 1 below.

$$Δ Ctot = Δ Ctop + Δ Cforce 1 + Δ Cforce 2 \qquad ( Expression 1 )$$

Assuming that the amount of fluctuation ΔCtop of the capacitance, Ctop, between the driving electrode 22 or pressure detecting electrode 23 and the touch detecting electrode 26 does not fluctuate while a conductor, such as the finger FG, is exerting a pressure onto the display surface DS, the amount of capacitance fluctuation ΔCtot in the sensor unit SP is expressed by Expression 2 below in a position falling within the thickness t of the elastic layer 21.

$$Δ Ctot = Δ Cforce 1 + Δ Cforce 2 \qquad ( Expression 2 )$$

Moreover, in a position deeper than the thickness t of the elastic layer 21, the amount of fluctuation ΔCforce1 of the capacitance Cforce1 between the driving electrode 22 and pressure detecting electrode 23 is small enough to be ignored; here, the amount of capacitance fluctuation ΔCtot in the sensor unit SP is expressed by Expression 3 below.

$$Δ Ctot = Δ Cforce 2 \qquad ( Expression 3 )$$

As described above, Expressions 2 and 3 demonstrate that the amount of capacitance fluctuation ΔCtot in the sensor unit SP is larger in a position falling within the thickness t of the elastic layer 21 than that in a position deeper than the thickness t of the elastic layer 21. Accordingly, the sensitivity of detection of a pressure onto the display surface DS exerted by a conductor, such as the finger FG, is high in a position falling within the thickness t of the elastic layer 21.

It is noted in FIG. 4 that the first to third driving electrodes 22 counted from the left side of FIG. 4 are individually driven by an identical driving signal TX1, and that the fourth to sixth driving electrodes 22 counted from the left side of FIG. 4 are individually driven by a driving signal TX2 different from the driving signal TX1. It is also noted that a detected signal F-RX is extracted from the pressure detecting electrodes 23.

It is noted that the lowercase x in FIG. 4 denotes the first direction HI in FIGS. 2 and 3, and that the lowercase z in FIG. 4 denotes the thickness direction of the elastic layer 21.

The elastic layer 21 preferably contains at least one material among an acrylic material, a silicon material, and an olefin material, and particularly preferably contains a silicon material.

This embodiment describes, by way of example, an instance where the elastic layer 21 is an adhesive layer having adhesion. The adhesive layer having adhesion can be obtained by mixing an adhesive component into the foregoing material for forming the elastic layer 21.

A method for manufacturing the display device 1 illustrated in FIG. 1 includes a step of forming the sensor unit SP. The step of forming the sensor unit SP includes the following: a step of forming the first conductive layer 24 including the driving electrode 22 and the touch detecting electrode 23 that are flush with each other, on the lower surface of the insulating layer 25 in this embodiment, in such a shape as to engage at least partly; a step of forming, closer to the display surface DS than the first conductive layer 24, the second conductive layer including the touch detecting electrode 26 overlapping at least a part of the pressure detecting electrode 23 in plan view; and a step of forming the elastic layer 21 provided at least between the first conductive layer 24 and the display unit DP, having a Young's modulus of 0.1 MPa or less, and having the thickness t equal to or smaller than the engagement pitch value 2 (IDL) between the driving electrode 22 and the pressure detecting electrode 23 in the first conductive layer 24.

The step of forming the second conductive layer including the touch detecting electrode 26 is forming the second conductive layer including the touch detecting electrode 26 onto a surface of a substrate 27 having the display surface DS, the surface facing the display surface DS. The step includes the following: after the step of forming the second conductive layer, a step of forming the insulating layer 25 so as to cover the second conductive layer; after the step of forming the insulating layer 25, a step of forming the first conductive layer 24 onto the insulating layer 25; after the step of forming the first conductive layer 24, a step of forming an adhesive layer that is the elastic layer 21 onto the first conductive layer 24 and the insulating layer 25; and after the step of forming the adhesive layer, which is the elastic layer 21, a step of joining the first conductive layer 24 and the insulating layer 25 to the display unit DP via the adhesive layer, which is the elastic layer 21, the first conductive layer 24 and the insulating layer 25 being provided on the surface facing the display surface DS of the substrate 27. Through these steps, the display device 1 can be manufactured.

Further, it is preferable to perform, before the joining step, a step of forming, as the uppermost layer of the display unit DP, the sealing layer 13 covering the display element DE.

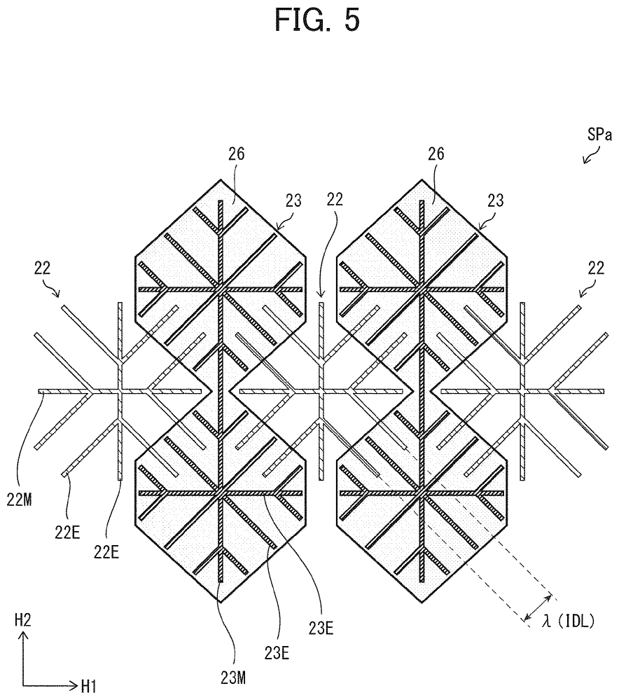

FIG. 5 is a plan view of the schematic electrode configuration of another sensor unit SPa that can be included in the display device 1 according to the first embodiment.

The sensor unit SPa illustrated in FIG. 5 includes a plurality of driving electrodes 22 having a comb shape, and a plurality of pressure detecting electrodes 23 having a comb shape.

The plurality of driving electrodes 22 included in the sensor unit SPa illustrated in FIG. 5 each includes the following: the trunk electrode portion 22M extending in the first direction HI; and the plurality of branch electrode portions 22E extending in a direction different from the first direction HI, and electrically connected to the trunk electrode portion 22M. Further, the plurality of pressure detecting electrodes 23 each includes the following: the trunk electrode portion 23M of the pressure detecting electrode 23, extending in the second direction H2 orthogonal to the first direction H1; and the plurality of branch electrode portions 23E of the pressure detecting electrode 23, extending in a direction different from the second direction H2, and electrically connected to the trunk electrode portion 23M of the pressure detecting electrode 23. Further, a plurality of touch detecting electrodes 26 is each provided so as to overlap at least the whole of the pressure detecting electrode 23 in plan view.

### Second Embodiment

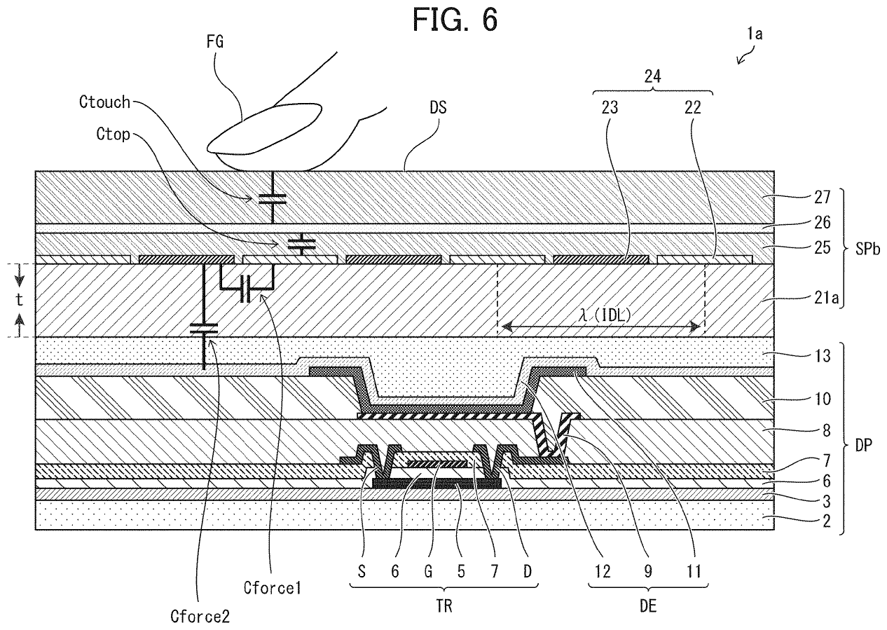

The second embodiment of the present disclosure will be next described with reference to FIG. 6. A sensor unit SPb included in a display device 1a according to this embodiment is different from that according to the first embodiment in that the sensor unit SPb includes an elastic layer 21a having no adhesion. The others are the same as those described in the first embodiment. For convenience in description, components having the same functions as those of the components illustrated in the drawings related to the first embodiment will be denoted by the same signs, and their descriptions will be omitted.

FIG. 6 is a cross-sectional view of the schematic configuration of the display device 1a according to the second embodiment.

The sensor unit SPb included in the display device 1a illustrated in FIG. 6 includes the elastic layer 21a having no adhesion.

The elastic layer 21a preferably contains at least one material among an acrylic material, a silicon material, and an olefin material, and particularly preferably contains a silicon material. It is noted that the Young's modulus and thickness, t, of the elastic layer 21a, which are the same as those described in the first embodiment, will not be elaborated upon here.

A method for manufacturing the display device 1a illustrated in FIG. 6 includes a step of forming the sensor unit SPb. A step of forming the elastic layer 21a, which is included in the step of forming the sensor unit SPb, is forming the elastic layer 21a onto the display unit DP. The step includes the following: after the step of forming the elastic layer 21a, a step of forming the first conductive layer 24 onto the elastic layer 21a; after the step of forming the first conductive layer 24, a step of forming the insulating layer 25 so as to cover the first conductive layer 24; and after the step of forming the insulating layer 25, a step of forming the second conductive layer including the touch detecting electrode 26 onto the insulating layer 25. Through these steps, the display device 1a can be manufactured.

### Third Embodiment

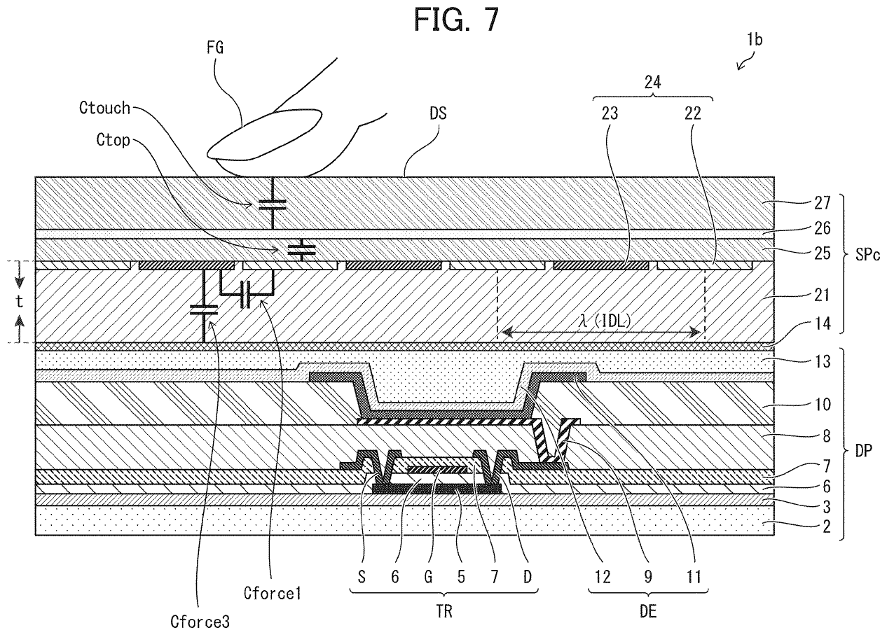

The third embodiment will be next described with reference to FIGS. 7 through 14. A sensor unit SPc included in a display device 1b according to this embodiment is different from those according to the first and second embodiments in that the sensor unit SPc includes a shield electrode 14 provided between its elastic layer 21 and sealing layer 13 so as to overlap at least a part of its driving electrode 22 in plan view. The others are the same as those described in the first and second embodiments. For convenience in description, components having the same functions as those of the components illustrated in the drawings related to the first and second embodiments will be denoted by the same signs, and their descriptions will be omitted.

FIG. 7 is a cross-sectional view of the schematic configuration of the display device 1b according to the third embodiment.

The sensor unit SPc included in the display device 1b illustrated in FIG. 7 includes the shield electrode 14 provided between the elastic layer 21 and the sealing layer 13 so as to overlap at least a part of the driving electrode 22 in plan view.

In the display device 1b, since the shield electrode 14 is provided above the second electrode 12, which is maintained at a constant potential during driving of the display unit DP, a capacitance Cforce3 is generated between the driving electrode 22 and the shield electrode 14. The capacitance Cforce3, which is the same as the capacitance Cforce2 described in the first embodiment except that the positions where the capacitances are generated are different, will not be elaborated upon here.

It is preferable that the shield electrode 14 containing a metal material do not overlap the display element DE in plan view.

It is also preferable that the shield electrode 14 containing a material that transmits light from the display element DE, be provided so as to overlap at least the driving electrode 22 in plan view.

As described above, the sensor unit SPc included in the display device 1b includes the shield electrode 14 and can thus prevent noise influence from the display unit DP when detecting a touch and a pressure onto the display surface DS.

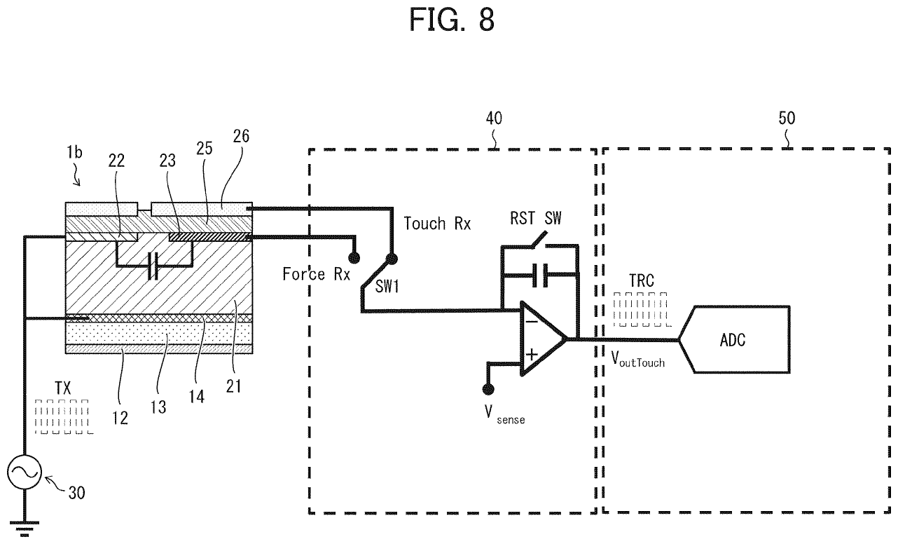

FIG. 8 is a diagram illustrating an example of how to drive the sensor unit SPc included in the display device 1b according to the third embodiment.

As illustrated in FIG. 8, the display device 1b may include the following: a signal generator 30 that generates a driving signal TX and supplies it to the driving electrode 22 and the shield electrode 14; a sense amplifying unit 40 that are for reading a detected signal Touch Rx from the touch detecting electrode 26, and a detected signal Force Rx from the pressure detecting electrode 23 alternately by the use of a switching element SW1; and an analog-to-digital converting unit 50.

Since the driving electrode 22 and the shield electrode 14 are supplied with an identical driving signal, the display device 1b illustrated in FIG. 8 can further prevent noise influence from the display unit DP when the sensor unit SPc detects a touch and a pressure onto the display surface DS.

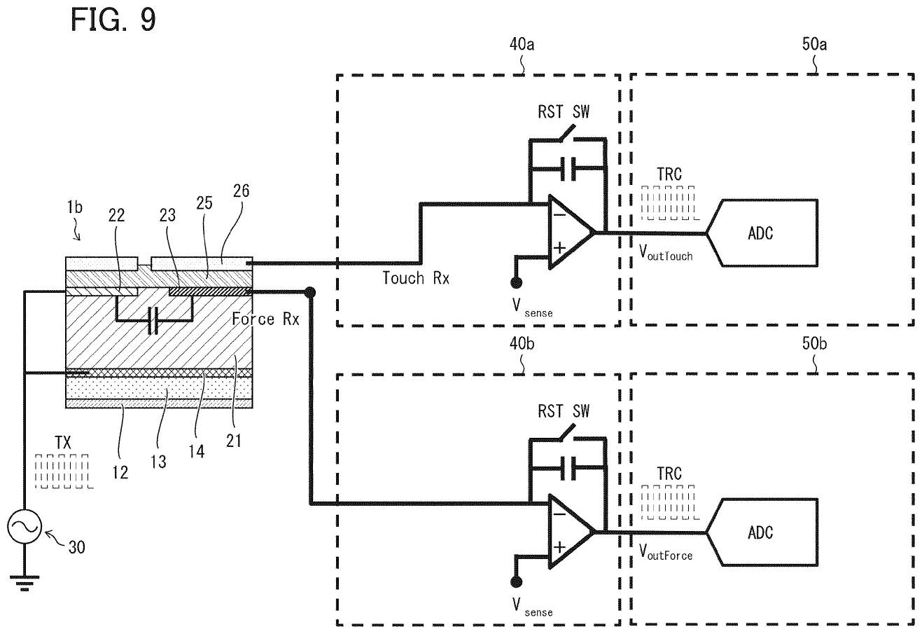

FIG. 9 is a diagram illustrating another example of how to drive the sensor unit SPc included in the display device 1b according to the third embodiment.

As illustrated in FIG. 9, the display device 1b may include the following: the signal generator 30 that generates the driving signal TX and supplies it to the driving electrode 22 and the shield electrode 14; a sense amplifying unit 40a and an analog-to-digital converting unit 50a that are for reading the detected signal Touch Rx from the touch detecting electrode 26; and a sense amplifying unit 40b and an analog-to-digital converting unit 50b that are for reading the detected signal Force Rx from the pressure detecting electrode 23.

Since the driving electrode 22 and the shield electrode 14 are supplied with an identical driving signal, the display device 1b illustrated in FIG. 9 can further prevent noise influence from the display unit DP when the sensor unit SPc detects a touch and a pressure onto the display surface DS. In addition, the sensor unit SPc can detect the touch and pressure onto the display surface DS at the same timing.

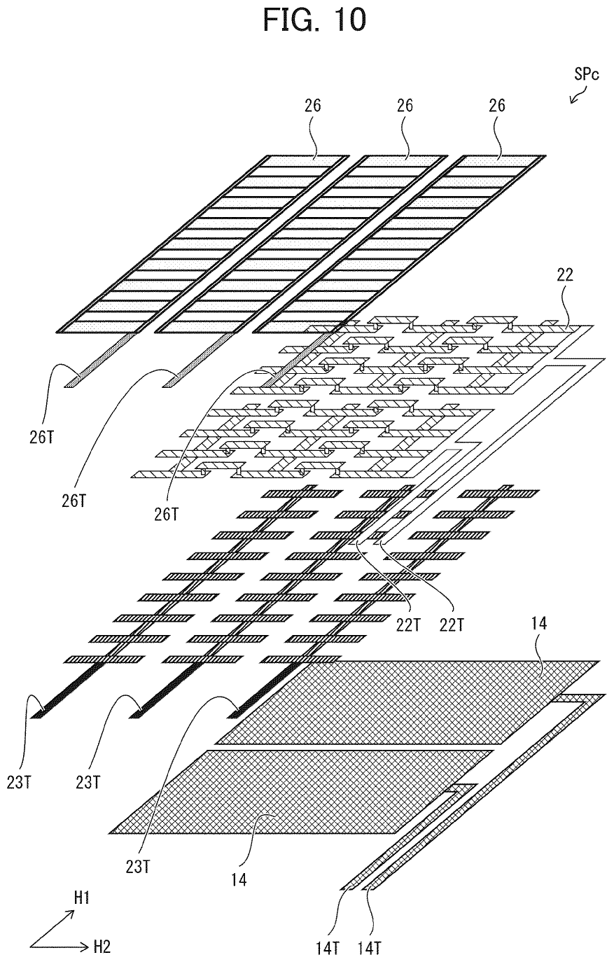

FIG. 10 is a perspective view of the schematic electrode configuration of the sensor unit SPc included in the display device 1b according to the third embodiment.

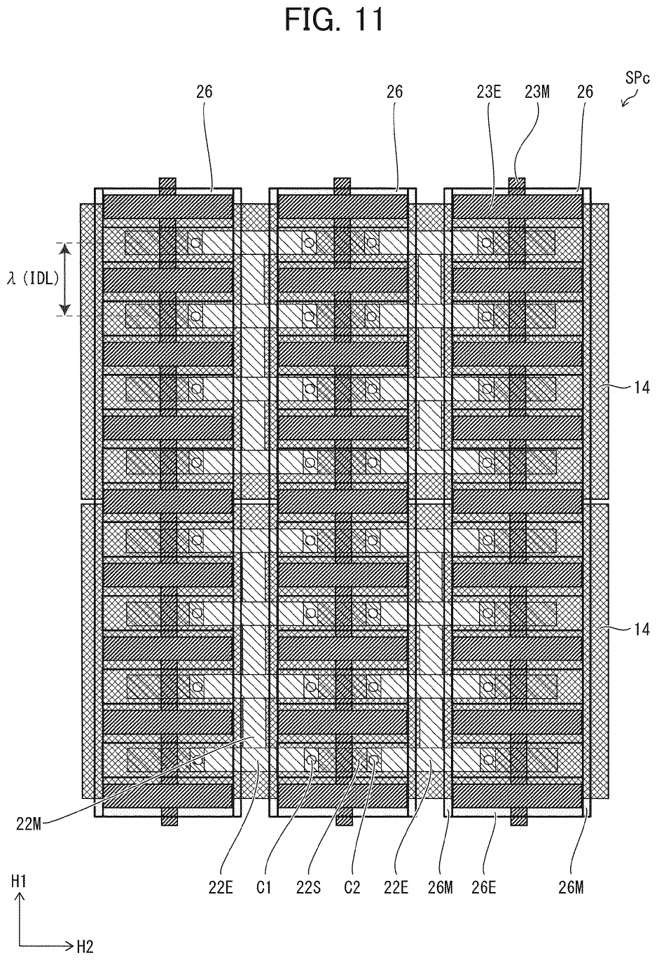

FIG. 11 is a plan view of the schematic electrode configuration of the sensor unit SPc included in the display device 1b according to the third embodiment.

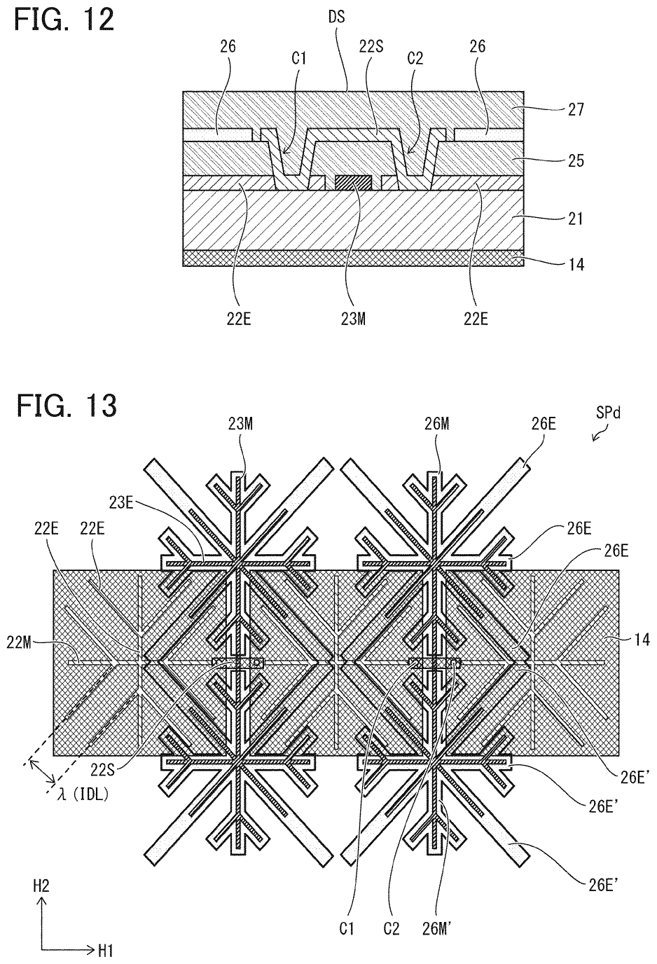

FIG. 12 is a cross-sectional view of a portion where the driving electrode 22 and the pressure detecting electrode 23 intersect with each other in the sensor unit SPc included in the display device 1b according to the third embodiment.

As illustrated in FIGS. 10 and 11, the plurality of touch detecting electrodes 26 included in the sensor unit SPc each includes the following: a trunk electrode portion 26M of the touch detecting electrode 26, extending in the first direction HI; and a plurality of branch electrode portions 26E of the touch detecting electrode 26, extending in the second direction H2 and electrically connected to the trunk electrode portion 26M of the touch detecting electrode 26.

As illustrated in FIGS. 11 and 12, the insulating layer 25 is provided so as to cover the first conductive layer 24 including the driving electrodes 22 and pressure detecting electrodes 23, and the second conductive layer including the touch detecting electrodes 26 is provided on the insulating layer 25. A coupling portion 22S of the driving electrode 22 and a part of the pressure detecting electrode 23 intersect with each other. The coupling portion 22s of the driving electrode 22 is provided in a first contact hole C1 formed in the insulating layer 25 overlapping a part of the driving electrode 22 in plan view, is provided in a second contact hole C2 formed in the insulating layer 25 overlapping another part of the driving electrode 22 in plan view, and is provided on the insulating layer 25 between the first contact hole C1 and second contact hole C2.

A method for manufacturing the display device 1b illustrated in FIG. 7 includes a step of forming the sensor unit SPc. The step of forming the sensor unit SPc includes the following: a step of forming the shield electrode 14 immediately onto the sealing layer 13, before the joining step described in the first embodiment and after the step of forming the sealing layer 13. The joining step is joining the first conductive layer 24 and the insulating layer 25 that are provided on the surface facing the display surface DS of the substrate 27, to the shield electrode 14 and the sealing layer 13 via an adhesive layer, which is the elastic layer 21, in such a manner that the shield electrode 14 overlaps at least a part of the driving electrode 22 in plan view. Through these steps, the display device 1b can be manufactured.

FIG. 13 is a plan view of the schematic electrode configuration of another sensor unit SPd that can be included in the display device 1b according to the third embodiment.

The plurality of driving electrodes 22 included in the sensor unit SPd illustrated in FIG. 13 each includes the following: the trunk electrode portion 22M extending in the first direction HI; and the plurality of branch electrode portions 22E extending in a direction different from the first direction HI, and electrically connected to the trunk electrode portion 22M. Further, the plurality of pressure detecting electrodes 23 each includes the following: the trunk electrode portion 23M of the pressure detecting electrode 23, extending in the second direction H2 orthogonal to the first direction H1; and the plurality of branch electrode portions 23E of the pressure detecting electrode 23, extending in a direction different from the second direction H2, and electrically connected to the trunk electrode portion 23M of the pressure detecting electrode 23.

The sensor unit SPd illustrated in FIG. 13 includes the shield electrode 14 provided so as to overlap at least a part of the plurality of driving electrodes 22 in plan view.

The plurality of touch detecting electrodes 26 included in the sensor unit SPd illustrated in FIG. 13 includes the following: a first trunk electrode portion 26M of the touch detecting electrodes 26, extending in the second direction H2; a second trunk electrode portion 26M′ of the touch detecting electrodes, extending in the second direction H2; a plurality of first branch electrode portions 26E of the touch detecting electrodes 26, extending in a direction different from the second direction H2, and electrically connected to the first trunk electrode portion 26M of the touch detecting electrodes 26; and a plurality of second branch electrode portions 26E′ of the touch detecting electrodes 26, extending in a direction different from the second direction H2, and electrically connected to the second trunk electrode portion 26M′ of the touch detecting electrodes 26. A part of the plurality of first branch electrode portions 26E of the touch detecting electrodes 26, and a part of the plurality of second branch electrode portions 26E′ of the touch detecting electrodes 26 are electrically connected together.

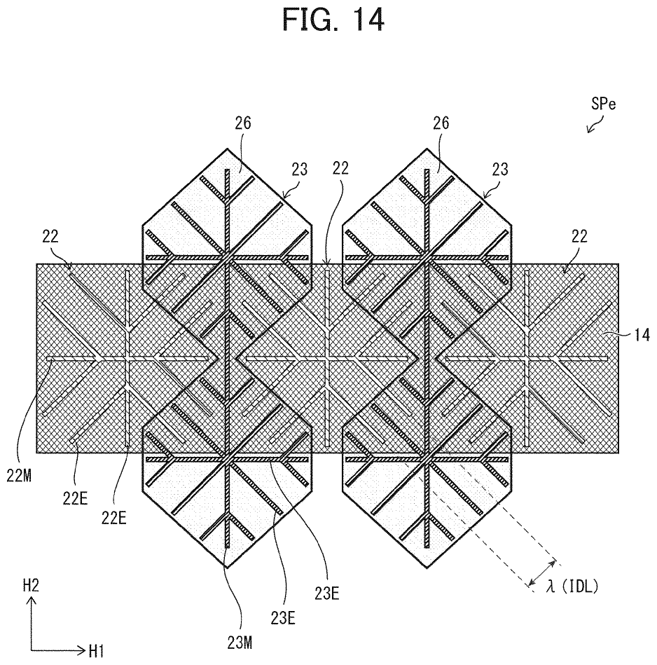

FIG. 14 is a plan view of the schematic electrode configuration of further another sensor unit SPe that can be included in the display device 1b according to the third embodiment.

The plurality of driving electrodes 22 included in the sensor unit SPe illustrated in FIG. 14 each includes the following: the trunk electrode portion 22M extending in the first direction HI; and the plurality of branch electrode portions 22E extending in a direction different from the first direction HI, and electrically connected to the trunk electrode portion 22M. Further, the plurality of pressure detecting electrodes 23 each includes the following: the trunk electrode portion 23M of the pressure detecting electrode 23, extending in the second direction H2 orthogonal to the first direction H1, and the plurality of branch electrode portions 23E of the pressure detecting electrode 23, extending in a direction different from the second direction H2, and electrically connected to the trunk electrode portion 23M of the pressure detecting electrode 23. Further, the plurality of touch detecting electrodes 26 is each provided so as to overlap at least the whole of the pressure detecting electrode 23 in plan view. Further, the sensor unit SPe illustrated in FIG. 14 includes the shield electrode 14 provided so as to overlap at least a part of the plurality of driving electrodes 22 in plan view.

### [Additional Note]

The present disclosure is not limited to the foregoing embodiments. Various modifications can be made within the scope of the claims. An embodiment that is obtained in combination as appropriate with the technical means disclosed in the respective embodiments is also encompassed within the technical scope of the present disclosure. Furthermore, combining the technical means disclosed in the respective embodiments can form a new technical feature.

### INDUSTRIAL APPLICABILITY

The present disclosure can be used for a display device, and a method for manufacturing the display device.

1. A display device comprising:
a display surface;
a display unit including a display element configured to emit light toward the display surface; and
a sensor unit provided between the display surface and the display unit, and configured to detect a touch and a pressure onto the display surface,
wherein the sensor unit includes
a first conductive layer including a driving electrode and a pressure detecting electrode that are flush with each other in such a shape as to engage at least partly,
a second conductive layer including a touch detecting electrode provided closer to the display surface than the first conductive layer so as to overlap at least a part of the pressure detecting electrode in a plan view, and
an elastic layer provided at least between the first conductive layer and the display unit, having a Young's modulus of 0.1 MPa or less, and having a thickness equal to or smaller than an engagement pitch value between the driving electrode and the pressure detecting electrode in the first conductive layer.

2. The display device according to claim 1, wherein
the display unit includes a sealing layer provided so as to cover the display element, and
the sensor unit is provided between the display surface and the sealing layer.

3. The display device according to claim 2, wherein the sensor unit includes a shield electrode provided between the elastic layer and the sealing layer so as to overlap at least a part of the driving electrode in the plan view.

4. The display device according to claim 3, wherein
the shield electrode contains a metal material, and
the shield electrode does not overlap the display element in the plan view.

5. The display device according to claim 3, wherein
the shield electrode contains a material that transmits the light, and
the shield electrode is provided so as to overlap at least the driving electrode in the plan view.

6. The display device according to claim 3, wherein the driving electrode and the shield electrode are supplied with an identical driving signal.

7. The display device according to claim 1, wherein the elastic layer is an adhesive layer.

8. The display device according to claim 1, comprising an insulating layer provided so as to cover the first conductive layer,
wherein the second conductive layer is provided on the insulating layer,
a coupling portion of the driving electrode and a part of the pressure detecting electrode intersect with each other, and
the coupling portion of the driving electrode is provided in a first contact hole formed in the insulating layer overlapping a part of the driving electrode in the plan view, is provided in a second contact hole formed in the insulating layer overlapping another part of the driving electrode in the plan view, and is provided on the insulating layer between the first contact hole and the second contact hole.

9. The display device according to claim 1, wherein
each of the driving electrode and the pressure detecting electrode includes
a trunk electrode portion extending in a first direction, and
a plurality of branch electrode portions extending in a second direction orthogonal to the first direction, and electrically connected to the trunk electrode portion.

10. The display device according to claim 1,
wherein the driving electrode includes
a trunk electrode portion extending in a first direction, and
a plurality of branch electrode portions extending in a direction different from the first direction, and electrically connected to the trunk electrode portion, and
wherein the pressure detecting electrode includes
a trunk electrode portion of the pressure detecting electrode, extending in a second direction orthogonal to the first direction, and
a plurality of branch electrode portions of the pressure detecting electrode, extending in a direction different from the second direction, and electrically connected to the trunk electrode portion of the pressure detecting electrode.

11. The display device according to claim 9- or 10, wherein the touch detecting electrode is provided so as to overlap at least a whole of the pressure detecting electrode in the plan view.

12. The display device according to claim 9, wherein
the touch detecting electrode includes
a trunk electrode portion of the touch detecting electrode, extending in the first direction, and
a plurality of branch electrode portions of the touch detecting electrode, extending in the second direction and electrically connected to the trunk electrode portion of the touch detecting electrode.

13. The display device according to claim 10,
wherein the touch detecting electrode includes
a first trunk electrode portion of the touch detecting electrode, extending in the second direction,
a second trunk electrode portion of the touch detecting electrode, extending in the second direction,
a plurality of first branch electrode portions of the touch detecting electrode, extending in the direction different from the second direction, and electrically connected to the first trunk electrode portion of the touch detecting electrode, and
a plurality of second branch electrode portions of the touch detecting electrode, extending in the direction different from the second direction, and electrically connected to the second trunk electrode portion of the touch detecting electrode, and
wherein a part of the plurality of first branch electrode portions of the touch detecting electrode, and a part of the plurality of second branch electrode portions of the touch detecting electrode are electrically connected together.

14. The display device according to claim 1, wherein the display element is either a light-emitting element including an emission layer, or a liquid-crystal display element including a liquid-crystal layer.

15. A method for manufacturing a display device,
the display device including
a display surface,
a display unit including a display element configured to emit light toward the display surface, and
a sensor unit provided between the display surface and the display unit, and configured to detect a touch and a pressure onto the display surface,
the method comprising a step of forming the sensor unit, the step including
a step of forming a first conductive layer including a driving electrode and a pressure detecting electrode that are flush with each other in such a shape as to engage at least partly,
a step of forming, closer to the display surface than the first conductive layer, a second conductive layer including a touch detecting electrode overlapping at least a part of the pressure detecting electrode in a plan view, and
a step of forming an elastic layer provided at least between the first conductive layer and the display unit, having a Young's modulus of 0.1 MPa or less, and having a thickness equal to or smaller than an engagement pitch value between the driving electrode and the pressure detecting electrode in the first conductive layer.

16. The method for manufacturing the display device according to claim 15,
wherein the step of forming the second conductive layer comprises forming the second conductive layer including the touch detecting electrode onto a surface of a substrate having the display surface, the surface facing the display surface, and
wherein the step of forming the second conductive layer includes
after the step of forming the second conductive layer, a step of forming an insulating layer so as to cover the second conductive layer,
after the step of forming the insulating layer, a step of forming the first conductive layer onto the insulating layer,
after the step of forming the first conductive layer, a step of forming an adhesive layer that is the elastic layer onto the first conductive layer and the insulating layer, and
after the step of forming the adhesive layer, a step of joining the first conductive layer and the insulating layer to the display unit via the adhesive layer, the first conductive layer and the insulating layer being provided on the surface facing the display surface of the substrate.

17. The method for manufacturing the display device according to claim 16, comprising, before the joining step, a step of forming, as an uppermost layer of the display unit, a sealing layer covering the display element.

18. The method for manufacturing the display device according to claim 17, comprising, before the joining step and after the step of forming the sealing layer, a step of forming a shield electrode immediately onto the sealing layer,
wherein the joining step comprises joining the first conductive layer and the insulating layer to the shield electrode and the sealing layer via the adhesive layer in such a manner that the shield electrode overlaps at least a part of the driving electrode in the plan view, the first conductive layer and the insulating layer being provided on the surface facing the display surface of the substrate.

19. The method for manufacturing the display device according to claim 15,
wherein the step of forming the elastic layer comprises forming the elastic layer onto the display unit, and
wherein the step of forming the elastic layer includes
after the step of forming the elastic layer, a step of forming the first conductive layer onto the elastic layer,
after the step of forming the first conductive layer, a step of forming an insulating layer so as to cover the first conductive layer, and
after the step of forming the insulating layer, a step of forming the second conductive layer onto the insulating layer.
